(19) United States
(12) Patent Application Publication
(10) Pub. No.: US 2005/0224819 A1
(43) Pub. Date: Oct. 13, 2005

(54) Imaging device and imaging method

(75) Inventor: Yasushi Araki, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 11/098,401

(22) Filed: Apr. 5, 2005

(30) Foreign Application Priority Data
Apr. 5, 2004 (JP) P.2004-110740

(51) Int. Cl. H01L 27/15

(52) U.S. Cl. 257/79

(57) ABSTRACT

An imaging device including a substrate having at least one photoelectric converting portion thereon, wherein the photoelectric converting portion contains at least one electrode, at least one organic dye and at least one inorganic material, the organic dye is arranged in contact with the inorganic material, and the electrode is an electrode that applies positive bias voltage to the inorganic material for 1 second or shorter in the time of image capturing, and an imaging method. Preferably the photoelectric converting portion is provided with a second electrode connected with the inorganic material.

This application is based on Japanese Patent application JP 2004-110740, filed Apr. 5, 2004, the entire content of which is hereby incorporated by reference. This claim for priority benefit is being filed concurrently with the filing of this application.

### BACKGROUND OF THE INVENTION

1. Technical Field of the Invention

The present invention relates to an imaging device and an imaging method, in particular relates to an imaging device using an organic dye high in quantum efficiency and an imaging method using the same.

2. Description of the Related Art

Photo-receptive devices or imaging devices comprising a lamination of a plurality of photoelectric converting devices having different spectral sensitivities have so far been proposed (Japanese Patent No. 3315213 and JP-A-7-38136 (the term “JP-A” as used herein means an “unexamined published Japanese patent application”)). On the other hand, photoelectric converting devices using an organic dye are excellent in spectroscopic characteristics due to the degree of freedom of the absorption wavelength control of organic dyes, so that they can be used as the photoelectric converting devices of an imaging device, and the elevation of use efficiency of light is promising. However, the photoelectric converting devices are low in quantum efficiency as compared with photoelectric converting devices using single crystal Si that are used in related art imaging devices. For example, although Grätzel cell using well-known titanium oxide/metal complex dye as the photoreceptor is a relatively high efficient device, it is low efficient as compared with a single crystal Si solar cell (see R. Knadler et al., Solar Energy Materials and Solar Cells, Vol. 30, p. 277 (1993) and H. Hagfeldt et al., Chem. Rev., Vol. 95, p. 49 (1995)). Therefore, for putting imaging devices using organic dyes to practical use, the development of improving techniques thereof has been desired.

### SUMMARY OF THE INVENTION

Objects of the invention are to provide an imaging device using an organic dye and having high quantum efficiency, and high durability (the aging stability of quantum efficiency), and to provide an imaging method.

The above objects of the invention were achieved by the following means.

(1) An imaging device comprising a substrate having at least one photoelectric converting portion thereon, wherein the photoelectric converting portion contains at least one electrode, at least one organic dye and at least one inorganic material, the organic dye is arranged in contact with the inorganic material, and the electrode is an electrode that applies positive bias voltage to the inorganic material for 1 second or shorter in the time of image capturing.

(2) The imaging device as described in the above (1), which satisfies μ×V/d>4×10⁻⁴, with the mobility of the inorganic material as μ (cm²/V·s) the distance between the inorganic material and the electrode as d (cm), and the positive bias voltage applied between the inorganic material and the electrode as V (V).

(3) The imaging device as described in the above (1) or (2), wherein the inorganic material is a semiconductor.

(4) The imaging device as described in any of the above (1) to (3), wherein the inorganic material contains any semiconductor of TiO₂, ZnO, SnO₂, ITO, ATO, FTO, IZO, SrTiO₃, BaTiO₃, Ge, Si, and the compounds belonging to III to V groups of the Periodic Table.

(5) The imaging device as described in any of the above (1) to (4), wherein the photoelectric converting portion has one more electrode connected with the inorganic material, and the electrode is an electrode that receives excited electrons from the inorganic material when the is irradiated with light, charges and accumulates the electrons, and discharges the accumulated electrons when light is shielded.

(6) The imaging device as described in any of the above (1) to (5), wherein at least two photoelectric converting portions are laminated.

(7) The imaging device as described in the above (6), wherein the laminated photoelectric converting portions absorb lights having different wavelengths respectively.

(8) The imaging device as described in the above (6), wherein at least three photoelectric converting portions are laminated, and the three photoelectric converting portions comprise at least a blue photoelectric converting portion, a green photoelectric converting portion and a red photoelectric converting portion.

(9) An imaging method by using the imaging device as described in any of the above (1) to (8) which comprises the process of applying positive bias voltage to the inorganic material for 1 second or shorter in the time of image capturing with the interelectrode material between or directly to the electrode connecting with the organic dye.

(10) The imaging method as described in the above (9), wherein the positive bias voltage satisfies the relationship of μ×V/d>4×10⁻⁴, taking the mobility of the inorganic material as μ (cm2/V·s), the distance between the inorganic material and the electrode as d (cm), and the positive bias voltage applied between the inorganic material and the electrode as V (V).

(11) The imaging method as described in the above (9) or (10), which comprises the processes of irradiating the photoelectric converting portion of the imaging device as described in the above item (5) with light to make the one more electrode connected with the inorganic material excite electrons, receiving the excited electrons from the inorganic material to charge and accumulate the electrons, and discharging the charged and accumulated electrons when the irradiating light is shielded.

The present invention is characterized in that positive bias voltage is applied to an inorganic material in image capture, and the improvement of quantum efficiency and the improvement of durability, which are the objects of the invention, can be achieved by the voltage application.

The invention is further characterized in that an organic material is connected with another electrode, which is to be called a donor electrode, in addition to the bias application, by which further improvement of quantum efficiency can be achieved. It is presumed that the effect of the improvement of quantum efficiency results from the prevention of invalidity of electrons by once storing generated excited electrons (that is, the imaging device in the invention has a capacity of storing electrons) and recombining them. Further, the stored electrons (which depend upon the irradiated quantity of light) can be read out as signals by electric charge transfer devices, etc.

By using the imaging device using an organic dye, preferably further having a donor electrode, and the imaging method in the invention of applying positive bias voltage to an inorganic material for 1 second or shorter in the time of image capturing, conspicuously high quantum efficiency and little attenuation of quantum efficiency can be achieved. Therefore, it is possible to obtain a high sensitivity and stable imaging device according to the invention.

### BRIEF DESCRIPTION OF THE DRAWINGS

FIG. 1 is a drawing explaining the behavior of photoelectron when reverse bias is applied to a related art p-n junction type photodiode using Si substrate.

FIG. 2 is a drawing explaining the behaviors of excitation, transition and recombination of the photoelectron in a dye-inorganic material system.

FIG. 3 is a drawing explaining the behaviors of excitation and transition of the photoelectron when an electron donor is added to a dye-inorganic material system in FIG. 2.

FIG. 4 is a drawing showing an embodiment of the constitution of an imaging device in the invention.

FIG. 5 is a drawing showing an embodiment of the constitution of an imaging device in the invention to which a second electrode is added.

FIG. 6 is graph la showing the relationship between the quantum efficiency and μ×V/d in Example 1 of the invention.

FIG. 7 is graph 1b showing the relationship between the aging quantum efficiency and μ×V/d in Example 1 of the invention.

FIG. 8 is graph 2a showing the relationship between the quantum efficiency and μ×V/d in Example 2 of the invention.

FIG. 9 is graph 2b showing the relationship between the aging quantum efficiency and μ×V/d in Example 2 of the invention.

### DETAILED DESCRIPTION OF THE INVENTION

The image capture sensor in the invention is described below.

It is important for the imaging device in the invention to comprise a substrate having at least one photoelectric converting portion thereon, the photoelectric converting portion contains at least one electrode, at least one organic dye and at least one inorganic material, the organic dye is arranged in contact with the inorganic material, and the positive bias voltage is applied to the inorganic material as against at least one electrode for 1 second or shorter. In the invention, the meaning that positive bias voltage is applied to the inorganic material as against the at least one electrode is, when the at least one electrode is ground, to apply voltage greater than 0 to the inorganic material, and of course when the at least one electrode has negative potential, it means to apply greater potential than that to the inorganic material.

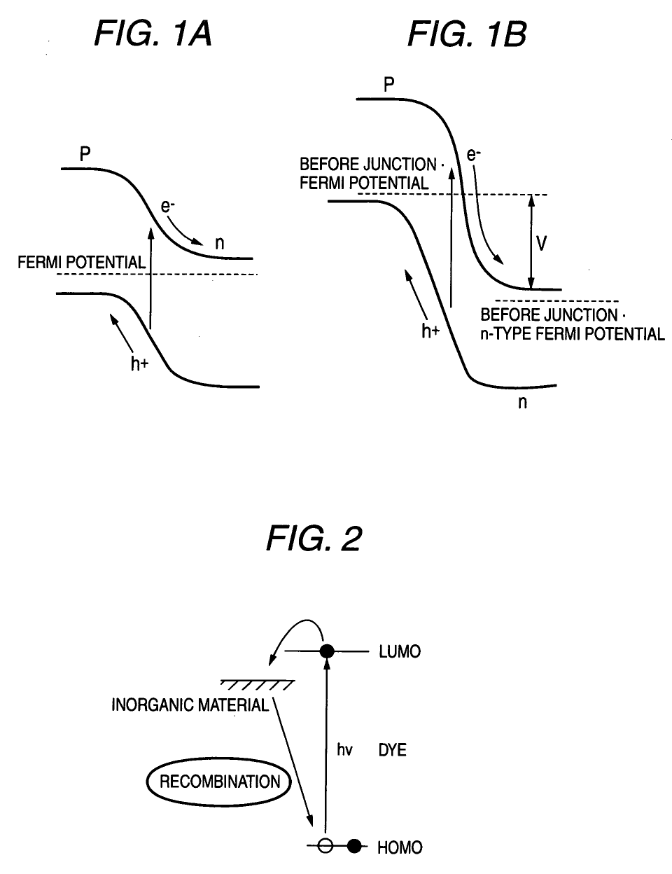

In related art photodiodes of p-n junction using Si, a technique of improving S/N by applying reverse bias is well known, but this is completely different from the bias application in the invention as described in the following. In related art Si photodiodes, a depletion layer widens by applying reverse bias such that negative bias is applied to p-type semiconductor side as against n-type semiconductor, and the applied voltage is used for the acceleration of the carrier generated by light, thereby the transfer efficiency is improved. This mechanism is shown in FIG. 1. FIG. 1A is the state of p-n junction of Si in the time when bias is not applied, and the diffusion of the carrier occurs until Fermi levels of p-type and n-type coincide and a depletion layer appears. As shown in FIG. 1B, since a depletion layer widens by the application of reverse bias here, the electrons excited by light are still more accelerated in the depletion layer, and so charge separation efficiency rises.

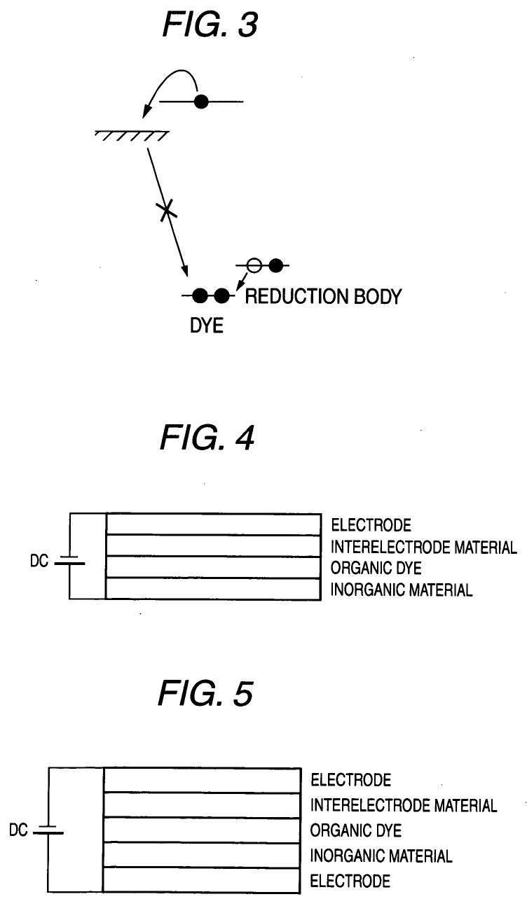

The meaning of bias application in the invention is different from the above mechanism, which is explained in FIG. 2, and that the conditions satisfied by applied bias are different is shown below. When the electrons of LUMO (excited molecular orbital) of a dye excited by light are injected into an inorganic material, the electrons and electron holes in the dye generated by light absorption are separated, but if the electrons and electron holes are recombined, it is not possible to effect photoelectric converting. The speed of injecting electrons of the dye excited by light to the inorganic material is extremely rapid, e.g., orders of from several ps to several hundred fs. However, the speed of recombination of the injected electrons with the electron holes of the dye is not so rapid, e.g., several ns order, so that it is important to lower the probability of the recombination. One well-known method of preventing the recombination of electrons with the electron holes of the dye is a method of reducing the electron holes of the dye. This mechanism is explained according to FIG. 3. In FIG. 3, a donor, which is a reducing material, is arranged on the side where a dye is not adsorbed and, after the electrons of the dye are excited by light and injected, the electrons are injected into the level where the electron holes are exist at extremely faster speed than the speed of recombination, by which the electrons that lost the electron holes to be recombined are inevitably to exist stably. Photoelectric converting efficiency rises by this mechanism. However, this system is not adapted to the photoelectric converting portion for use for an imaging device. The reason is that a reversible reaction is necessary in the case of imaging device.

As a technique of reversibly improving photoelectric converting characteristics, it has been found that to apply positive bias voltage as against the at least one electrode to an inorganic material for 1 second or shorter is effective in the invention. The fact that the condition of 1 second or shorter is very important in the invention is described below. An organic dye is used in the invention, and if bias voltage is applied to the organic dye, the durability of device, i.e., the durability of the organic dye deteriorates. That is, even if the photoelectric converting characteristics are improved, the durability of organic dye deteriorates, so that the performance is so far from practicable. However, it has been found by the invention that when the time of application of bias voltage is 1 second or shorter, the deterioration of the durability of organic dye can be extremely suppressed and, at the same time, photoelectric converting characteristics can be improved. The time of application of bias voltage is more preferably 100 ms or shorter, still preferably 10 ms or shorter, and still more preferably 1 ms or shorter.

However, the time of application is preferably at least 10 ns or longer since the effect of the invention cannot be exhibited without application of bias voltage. In addition, when the application time exceeds 1 second, the deterioration of organic dyes becomes conspicuous.

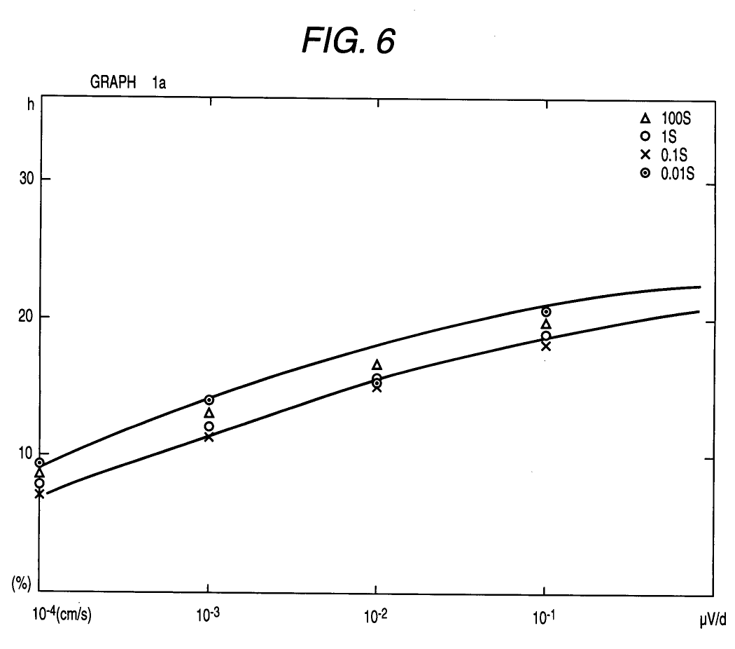

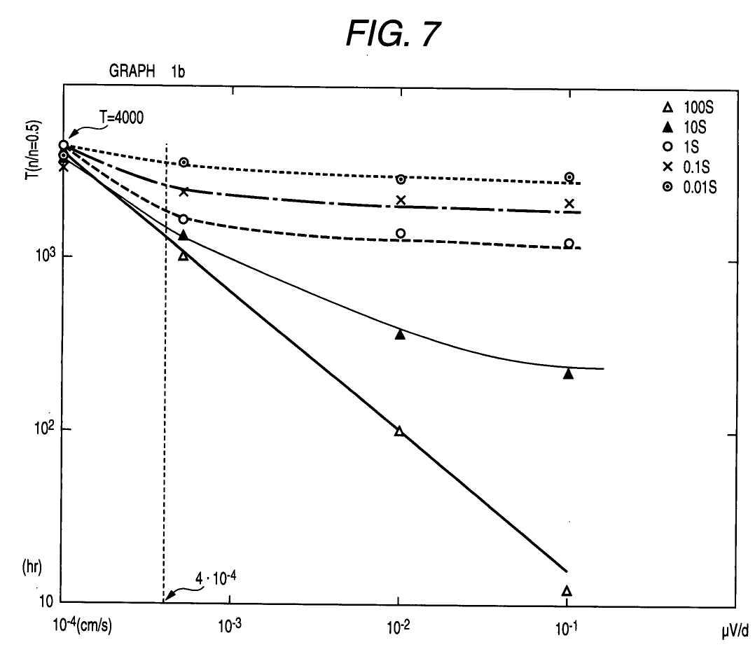

It is very preferred in the invention that the imaging device satisfies the relationship of μ×V/d>4×10⁻⁴, with the mobility of an inorganic material onto which an organic dye is adsorbed as μ (cm²/V·s), the distance between the inorganic material and the electrode as d (cm), and the positive bias voltage applied between the inorganic material and the electrode as V (V), more preferably μ×V/d>4×10⁻³, still more preferably μ×V/d>4×10⁻², and most preferably μ×V/d>4×10⁻¹. This is explained by graph 1a in Example 1 shown in FIG. 6. The continuous line in FIG. 6 (graph 1a) is the quantum efficiency of a photoelectric converting device with the abscissa as μ×V/d. This means that the greater the μ×V/d, the more improved is the efficiency. The mechanism is presumed as follows by the inventor. In FIG. 2, the state that an electron is injected from LUMO (excited molecular orbital) of a dye into the level to which the electron of an inorganic material adsorbed with the dye can enter is considered below. When mobility μ, and electric field E in the organic material, are present here, the electron receives drift speed of μ×E from the electric field, and it is construed that one condition that the drift speed can resist the recombination speed of the electron hole of dye and the electron in the inorganic material may be μ×V/d>4×10⁻⁴. On the other hand, graph 1b shown in FIG. 7 is the durability of an device, and when μ×V/d is made great, the durability of the device broadly deteriorates, but it can be seen that the deterioration of the durability can be greatly suppressed when the time of application is 1 second or shorter that is an indispensable requisite of the invention. In particular, the effect can be conspicuously improved in the range of satisfying μ×V/d>4×120⁻⁴ so that it is very preferred in the invention to satisfy μ×V/d>4×10 ⁻⁴.

As inorganic materials onto which dyes are adsorbed, materials that are capable of injection of electrons from LUMO (excited molecular orbital) of dyes are preferred in the invention, and semiconductors are preferred. Semiconductors applicable to the invention are semiconductors according to general definition of the semiconductor, and materials having electrical conductance of from 10³ to 10⁻¹⁰ s/cm at room temperature. As the preferred materials of semiconductors, in addition to semiconductors of simple substance such as silicon and germanium, semiconductors of the compounds typified by metal chalcogenides and compounds having a perovskite structure can be used. As metal the examples of chalcogenides, oxides of titanium, tin, zinc, iron, tungsten, zirconium, hafnium, strontium, indium, cerium, yttrium, lanthanum, vanadium, niobium and tantalum, sulfides of cadmium, zinc, lead, silver, antimony and bismuth, selenides of cadmium and lead, and cadmium telluride are preferably exemplified. As semiconductors of other compounds, phosphides of zinc, gallium, indium and cadmium, gallium arsenide, copper-indium selenide, and copper-indium sulfide are exemplified. As the compounds having a perovskite structure, strontium titanate, calcium titanate, sodium titanate, varium titanate, and potassium niobate can be exemplified, but the invention is of course not limited to these compounds. As particularly preferred materials for use in the invention, semiconductors of TiO₂, ZnO, SnO₂, ITO (indium-tin oxide), ATO (antimony-tin oxide), IZO (indium-zinc oxide), FTO (fluorine-added tin oxide), SrTiO₃, BaTiO₂, Ge, Si, and the compounds belonging to III to V groups of the Periodic Table can be exemplified.

Any organic dye can be used in the invention, e.g., metal complex dyes, cyanine dyes, merocyanine dyes, phenylxanthene dyes, triphenylmethane dyes, rhodacyanine dyes, xanthene dyes, large ring azaannulene dyes, azulene dyes, naphthoquinone dyes, anthraquinone dyes, cyclic compounds of condensed polycyclic aromatic compounds, such as anthracene and pyrene, cyclic compounds formed by condensation of aromatic rings or heterocyclic compounds, quinoline having a squarylium group and a croconic methine group as the bonding chains, nitrogen-containing compounds such as benzothiazole and benzoxazole, and dyes analogous to cyanine dyes bonded by a squarylium group and a croconic methine group can be preferably used. In metal complex dyes, dithiol metal complex dyes, metallic phthalocyanine dyes, metallic porphyrin dyes, and ruthenium complex dyes are preferred, and ruthenium complex dyes are particularly preferred. As ruthenium complex dyes, the complex dyes disclosed in U.S. Pat. Nos. 4,927,721, 4,684,537, 5,084,365, 5,350,644, 5,463,057, 5,525,440, JP-A-7-249790, JP-T-10-504512 (the term “JP-T” as used herein means a “published Japanese translation of PCT patent application”), WO 98/50393, and JP-A-2000-26487 are exemplified. The specific examples of polymethine dyes such as cyanine dyes, merocyanine dyes, and squarylium dyes are disclosed in JP-A-11-35836, JP-A-11-67285, JP-A-11-86916, JP-A-11-97725, JP-A-11-158395, JP-A-11-163378, JP-A-11-214730, JP-A-11-214731, JP-A-11-238905, JP-A-2000-26487, EP Nos. 892411, 911841 and 991092.

In the invention, an organic dye is arranged in contact with an inorganic material. The manner of arrangement is not particularly restricted but it is preferred that an organic dye be adsorbed onto an inorganic material. The manner of adsorption may be any of physical adsorption and chemical adsorption.

The preferred constitutions of the photoelectric converting portion in the invention are described below. For example, as shown in FIG. 4, there is a constitution comprising an inorganic material, an organic dye, an interelectrode material, and at least one electrode from the lower part. Positive bias voltage is applied as shown by electric source sign DC in FIG. 4. It is also very preferred to provide one more electrode (a donor electrode) under the inorganic material as shown in FIG. 5. This constitution is preferred for the reason that the characteristics of the inorganic material injected from the organic dye and electrode characteristics can be separated. In addition, it is preferred for the inorganic material to have a great surface area so as to be capable of arranging a great amount of dye, and the inorganic material bas preferably been subjected to surface widening treatment. For example, it is preferred to form a porous film by sintering particles of inorganic materials, or it is also preferred to perform treatment of perforation of a thin film to increase a surface area. The donor electrode provided in contact with the inorganic material is preferably the following transparent electroconductive film. Further, it is also preferred that the inorganic material be a transparent electroconductive film, and in this case the inorganic material also has a function as an electrode.

As transparent electroconductive films, any well-known film can be used, e.g., metals, alloys, metallic oxides, organic electroconductive compounds and mixtures of these materials are preferred, specifically electroconductive metallic oxides, e.g., tin oxide, zinc oxide, indium oxide, IZO (indium-zinc oxide), and ITO (indium-tin oxide), metals, e.g., gold, platinum, silver, chromium and nickel, mixtures and laminations of these metals and electroconductive metallic oxides, inorganic electroconductive materials, e.g., copper iodide and copper sulfide, organic electroconductive materials, e.g., polyaniline, polythiophene and polypyrrole, and laminates of these inorganic and organic electroconductive materials and ITO are exemplified. In addition to the above, those described in compiled by Yutaka Sawada, Tomei Doden-Maku no Shin-Tenkai (Novel Development of Transparent Electro-conductive Films), CMC Publishing Co., Ltd. (1999), and Japan Society for the Promotion of Science, Tomei Doden-Maku no Gijutsu (Techniques of Transparent Electroconductive Films), Ohmsha Ltd. (1999) may be used.

Any material can also be used as the at least one electrode in the invention, but the transparent electroconductive films described above are preferred. Of course other metals, oxides, semiconductors maybe used, for example, optional combinations selected from the following metals may be used, e.g., Li, Na, Mg, K, Ca, Rb, Sr, Cs, Ba, Fr, Ra, Sc, Ti, Y, Zr, Hf, V, Nb, Ta, Cr, Mo, W, Mn, Tc, Re, Fe, Ru, Os, Co, Rh, Ir, Ni, Pd, Pt, Cu, Ag, Au, Zn, Cd, Al, Ga, In, Tl, Si, Ge, Sn, Pb, P, As, Sb, Bi, Se, Te, Po, Br, I, At, B, C, N, F, O, S and N.

As the interelectrode materials, any compound can be used, e.g., dielectric substances, electric conductors, inorganic semiconductors, organic semiconductors, and electrolytes, but organic semiconductors, and molten salt electrolytes and solid state electrolytes of electrolytes are preferred. For example, as the examples of organic semiconductors, there are electron hole-carrying materials and electron-carrying materials, and as electron hole-carrying materials, poly-N-vinyl-carbazole derivatives, polyphenylenevinylene derivatives, polyphenylene, polythiophene, polymethylphenylsilane, polyaniline, triazole derivatives, oxadiazole derivatives, imidazole derivatives, polyarylalkane derivatives, pyrazoline derivatives, pyrazolone derivatives, phenylene-diamine derivatives, arylamine derivatives, amino-substituted chalcone derivatives, oxazole derivatives, carbazole derivatives, styrylanthracene derivatives, fluorenone derivatives, hydrazone derivatives, stilbene derivatives, porphyrin derivatives (phthalocyanine, etc.), aromatic tertiary amine compounds, styrylamine compounds, butadiene compounds, benzidine derivatives, polystyrene derivatives, triphenylmethane derivatives, tetraphenyl-benzine derivatives, and starburst polyamine derivatives can be used. As the examples of electron-carrying materials, oxadiazole derivatives, triazole derivatives, triazine derivatives, nitro-substituted fluorenone derivatives, thiopyran dioxide derivatives, diphenylquinone derivatives, perylenetetracarboxyl derivatives, anthraquinonedimethane derivatives, fluorenylidenemethane derivatives, anthrone derivatives, perinone derivatives, oxine derivatives, and quinoline complex derivatives are exemplified.

Molten salt electrolytes are salts that are in a liquid state at room temperature or low melting point salts, and well-known electrolytes, e.g., pyridinium salts, imidazolium salts, and triazolium salts disclosed, e.g., in WO 95/18456, JP-A-8-259543, and Denki Kagaku (Electrochemistry), Vol. 65, No. 11, p. 923 (1997) can be exemplified. Molten salts that are in a liquid state at 100° C. or lower, in particular at near room temperature, are preferred.

As the molten salts that can be preferably used in the invention, those represented by formulae (Y-a), (Y-b) and (Y-c) in JP-A-2002-299678 and the exemplified compounds thereof are cited.

The above molten salt electrolytes are preferably in a molten state at ordinary temperature, and preferably solvents are not used. The later-described solvents may be added, but the content of molten salt is preferably 50 weight % or more based on the total electrolyte composition, particularly preferably 90 weight % or more.

As gel state electrolytes, the above described molten state electrolytes and electrolytic solutions can be used by gelation (solidification) by means of the addition of a polymer, the addition of an oil gelling agent, the polymerization containing a polyfunctional monomer, and the crosslinking reaction of a polymer. When gelation is performed by the addition of a polymer, the compounds described in J. R. MacCallum and C. A. Vincent, ELSEVIER APPLIED SCIENCE, “Polymer Electrolyte Reviews—1 and 2” can be used, and polyacrylonitrile and polyvinylidene fluoride can be particularly preferably used. When gelation is performed by the addition of an oil gelling agent, the compounds described in Chem. Soc. Japan, Ind. Chem. Sec., Vol. 46, p. 779 (1943), J. Am. Chem. Soc., Vol. 111, p. 5542 (1989), J. Chem. Soc., Chem. Commun., 1993, p. 390, Angew. Chem. Int. Ed. Engl., Vol. 35, p. 1949 (1996), Chem. Lett., 1996, p. 885, J. Chem. Soc., Chem. Commun., 1997, p. 545 can be used. Preferred compounds are those having an amido structure in the molecular structure. The examples of gelled electrolytic solutions are disclosed in JP-A-11-185863, and the examples of gelled molten salt electrolytes are disclosed in JP-A-2000-58140, and these compounds can also be used in the invention.

When electrolytes are gelled by crosslinking reaction of polymers, it is preferred to use polymers containing crosslinkable reactive groups and a crosslinking agent in combination. In this case, preferred crosslinkable reactive groups are an amino group, a nitrogen-containing heterocyclic rings (e.g., a pyridine ring, an imidazole ring, a thiazole ring, an oxazole ring, a triazole ring, a morpholine ring, a piperidine ring, and a piperazine ring), and preferred crosslinking agents are bifunctional or higher reagents capable of electrophilic reaction with a nitrogen atom (e.g., alkyl halide, aralkyl halide, sulfonic ester, acid anhydride, acid chloride, isocyanate, an α, β-unsaturated sulfonyl group, an α, β-unsaturated carbonyl group, an α, β-unsaturated nitrile group, etc.). The crosslinking techniques disclosed in JP-A-2000-17076 and JP-A-2000-86724 can also be applied to the invention.

As polymer compounds, those which dissolve electrolytic salts by themselves and show an ionic conducting property, and polymer compounds that cannot dissolve electrolytic salts by themselves but come to show an ionic conducting property by using a solvent capable of dissolving electrolytic salts can be used.

As the former polymer compounds, e.g., polyethylene glycol, polymer compounds having the structure of polyacrylic acid, polymethacrylic acid, polyethylene oxide, polypropylene oxide, polyvinyl alcohol, polyphosphazen, polysilane, or copolymers of them at the main chain, and having a polyoxyethylene structure at the side chains can be used. These polymer compounds capable of dissolving electrolytic salts by themselves can also be used in combination with the solvents capable of dissolving electrolytic salts.

In contrast to these compounds, as the latter compounds, e.g., polyvinyl chloride, polyacrylonitrile, polyethylene, polypropylene, polyester, polyacrylate and copolymers of these compounds can be used. These compounds may have a crosslinking structure.

In the invention, it is preferred that at least two or more pairs of the photoelectric converting portions are laminated, more preferably three or more pairs, for the reason that the efficiency of light utilization can be increased by such a structure. In addition, when at least three pairs of the photoelectric converting portions comprise a blue photoelectric converting portion, a green photoelectric converting portion and a red photoelectric converting portion, one pixel can function as a full color imaging device so that very preferred.

As the substrates for use in the invention, Si substrates such as an Si wafer loading charge transfer device, and an Si wafer loading the driving circuit of CMOS image sensor are most preferred, but any substrate, e.g., a semiconductor substrate, a glass substrate and a plastic substrate can be used in the invention.

### EXAMPLE

### Example 1

The present invention is specifically described below with reference to examples, but the invention is not limited thereto.

On the electric conductive side of an electric conductive glass sheet (TCO glass-U, manufactured by Asahi Glass Co., Ltd., processed by cutting in a size of 20 cm×20 cm) coated with fluorine-doped tin oxide, a titanium oxide sol solution (manufactured by Solaronics Co., particle size of titanium oxide: 9 nm) was coated with a glass rod. After coating, the glass sheet was air-dried at room temperature for one day. The glass sheet was then put in an electric furnace (muffle furnace model FP-32, manufactured by Yamato Scientific Co., Ltd.) and baked at 450° C. for 30 minutes. After being taken out of the furnace and cooled, the glass sheet was immersed in an ethanol solution of ruthenium tris-bipyridine complex dye (3×10⁻⁴ mol/liter) for 3 hours. The dye-adsorbed glass sheet was immersed in 4-t-butyl pyridine for 15 minutes, and then washed with ethanol and subjected to natural drying. The thickness of the thus-obtained photosensitive layer was 10 μm, and the coating amount of the semiconductor fine particles was 20 g/m². The surface resistance of the electric conductive glass was about 30 Ω/□. On the top of the thus-manufactured TiO₂ semiconductor electrode substrate (2 cm×2 cm) sensitized with a dye, a platinum deposited glass sheet having the same size was superimposed with spacers of various thicknesses (0.1 μm, 1 μm, 10 μm or 25 μm), and an electrolyte (LiN(SO₂CF₃)₂ (0.5 M)/methoxyacetonitrile) was permeated into the space between two sheets of glass by utilizing a capillary phenomenon to thereby form an device.

The above-prepared photo-receptive device was subjected to irradiation with white light of 1 mW to 50 μW for 1/100 seconds and the electric current passed through was measured. The external quantum efficiency was computed from the electric current passed through at that time and the number of photons of the light source, and the results obtained were shown in graph 1a in FIG. 6. Further, voltage was applied to the transparent electrode with the dye-adsorbed titanium oxide electrode for t seconds (100 s, 10 s, 1 s, 0.1 s or 0.01 s) so that the voltage was positive to the platinum electrode, and the external quantum efficiency (h) was computed from the electric current passed through at that time and the number of photons of the light source. The electric current passed through was 0 in the case where voltage was applied but light was not radiated. This test was repeated every 10 seconds, and the time when the quantum efficiency decreased to half (T (n/n=0.5)) was found and the results were graphed and shown in FIG. 7.

As is apparent from these graphs, when the application of voltage is 1 second or shorter, the deterioration of durability greatly decreases, although the quantum efficiency increases when μ×V/d is made great. In particular, in the range of μ×V/d>4×10⁻⁴, the durability hardly deteriorates and quantum efficiency can be bettered with the application time of 1 s or shorter, and so very preferred.

### Example 2

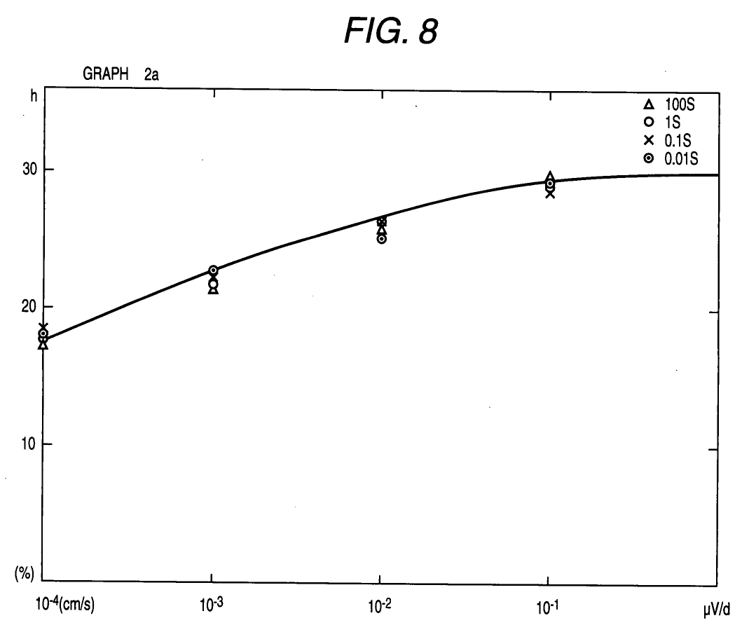

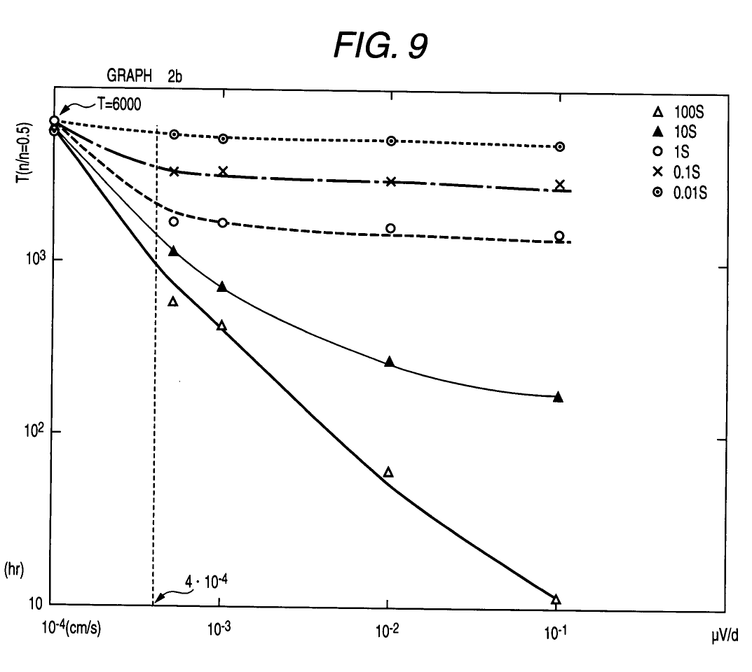

An ITO film having a surface resistance of 7 Ω/□ and a thickness of 0.20 μm was formed by a reactive sputtering method on a Corning 1737 glass sheet (25 mm×25 mm). Patterning of the ITO was carried out on two lines of 5 mm wide and 5 mm interval. A film of Compound 1 shown below having a thickness of 10 nm was formed thereon by a vacuum film-forming method. After that, Alq(tris-8-hydroxyquinoline aluminum) was film-formed in a thickness of 80 nm by a vacuum film-forming method, and in the last place, Al was film-formed in a thickness of 0.5 μm by vacuum deposition. The same two lines as those of ITO film were formed on the last Al film so as to intersect the lines of ITO via a mask. The external quantum efficiency was computed in the same manner as in Example 1, and the results were graphed and shown in FIG. 8. Further, when the electric current passed although light was not radiated, the computation was performed by taking the difference between the electric current passed in the time when light was radiated and that in the time not radiated. This test was repeated every 10 seconds, and the time when the quantum efficiency decreased to half was found, and the results were graphed and shown in FIG. 9.

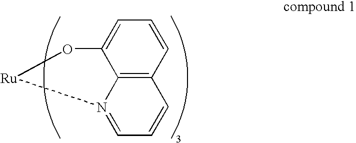

Completely the same effect as in Example 1 can be read from these graphs. That is, when the application of voltage is 1 second or shorter, the deterioration of durability greatly decreases, although the quantum efficiency increases when μ×V/d is made great. In particular, in the range of μ×V/d>4×10⁴, the durability hardly deteriorates with the application time of 1 s or shorter, from which it can be seen that quantum efficiency can be improved.

1. An imaging device comprising a substrate and a first photoelectric converting portion on the substrate, wherein
the first photoelectric converting portion comprises:
a first electrode; at least one organic dye; and at least one inorganic material,
the organic dye is arranged in contact with the inorganic material, and
the first electrode is an electrode that applies a positive bias voltage to the inorganic material for 1 second or shorter when an image is captured.

2. The imaging device according to claim 1, wherein the imaging device satisfies a relationship of μ×V/d>4×10⁻⁴, in which μ is a mobility of the inorganic material, d is a distance between the inorganic material and the first electrode, and V is the positive bias voltage applied between the inorganic material and the first electrode.

3. The imaging device according to claim 1, wherein the inorganic material is a semiconductor.

4. The imaging device according to claim 1, wherein the inorganic material contains any semiconductor of TiO₂, ZnO, SnO₂, ITO, ATO, FTO, IZO, SrTiO₃, BaTiO₃, Ge, Si, and compounds belonging to III to V groups of the Periodic Table.

5. The imaging device according to claim 1, wherein
the photoelectric converting portion further comprises a second electrode connected with the inorganic material, and
the second electrode is an electrode that receives excited electrons from the inorganic material when the photoelectric converting portion is irradiated with light, charges and accumulates the electrons, and discharges the accumulated electrons when light is shielded.

6. The imaging device according to claim 1, wherein the imaging device further comprises a second photoelectric converting portion, and the first and the second photoelectric converting portions are laminated.

7. The imaging device according to claim 6, wherein the first and the second photoelectric converting portions absorb lights having different wavelengths respectively.

8. The imaging device according to claim 6, wherein
the imaging device further comprises a third photoelectric converting portion,
the first, the second and the third photoelectric converting portions are laminated, and
the laminated photoelectric converting portions comprise a blue photoelectric converting portion, a green photoelectric converting portion and a red photoelectric converting portion.

9. An imaging method by using the imaging device according to claim 1, comprising the steps of
applying the positive bias voltage as against the first electrode connecting to the organic dye with an interelectrode material or directly connecting to the organic dye to the inorganic material for 1 second or shorter when the image is captured.

10. The imaging method according to claim 9, wherein the imaging device satisfies a relationship of μ×V/d>4×10⁻⁴, in which μ is a mobility of the inorganic material, d is a distance between the inorganic material and the first electrode, and V is the positive bias voltage applied between the inorganic material and the first electrode.

11. The imaging method according to claim 9, which further comprises:
irradiating the first photoelectric converting portion of the imaging device according to claim 5 with light to make the second electrode connected with the inorganic material excite electrons;
receiving the excited electrons from the inorganic material to charge and accumulate the electrons, and
discharging the charged and accumulated electrons when irradiating light is shielded.
